(19) United States
(12) Patent Application Publication
(10) Pub. No.: US 2026/0101583 A1
(43) Pub. Date: Apr. 9, 2026

(54) SEMICONDUCTOR DEVICE WITH ISOLATION STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: WEI-CHI LIN, HSINCHU COUNTY (TW); MENG CHI HANG, HSINCHU CITY (TW); CHIEN-LIN TSENG, HSINCHU COUNTY (TW); CHUNG-CHUAN TSENG, HSINCHU CITY (TW)

(21) Appl. No.: 18/910,039

(22) Filed: Oct. 9, 2024

(51) Int. Cl. H01L 27/12; H01L 21/306; H01L 21/3065; H01L 21/761; H01L 21/762

(52) U.S. Cl. CPC H10D 86/201; H10P 90/1906; H10W 10/014; H10W 10/031; H10W 10/061; H10W 10/17; H10W 10/181; H10W 10/30; H10P 50/242; H10P 50/642

(57) ABSTRACT

A semiconductor device is provided. The semiconductor device includes a first semiconductive region, a second semiconductive region, an isolation structure and at least one inner insulating via. The isolation structure is formed between the first semiconductive region and the second semiconductive region and includes an isolation bottom formed beneath the second semiconductive region and an isolation ring. The isolation ring includes a plurality of insulating regions and a plurality of doped regions formed alternately. The isolation bottom and the plurality of insulating regions have insulating materials. The plurality of doped regions have dopants of a conductivity type complementary to those of the first and second semiconductive regions. The isolation ring has a lower portion connecting the isolation bottom and an upper portion surrounding the second semiconductive region. The inner insulating via is formed in the second semiconductive region, on the isolation bottom and surrounded by the isolation ring.

### BACKGROUND

Semiconductor devices are used in a large number of electronic devices, such as computers, cell phones, and others. Semiconductor devices comprise integrated circuits that are formed on semiconductor wafers by depositing many types of thin films of material over the semiconductor wafers, and patterning the thin films of material to form the integrated circuits. Integrated circuits include field-effect transistors (FETs) such as metal oxide semiconductor (MOS) transistors.

One of the goals of the semiconductor industry is to continue shrinking the size and increasing the speed of individual FETs. Silicon on insulator (SOI) devices have been recognized as one of the possible solutions to enable continued scaling. SOI devices offer a number of advantages over bulk devices. For example, SOI devices exhibit very low junction capacitance compared to bulk devices. The source and drain junction capacitances are almost entirely eliminated.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor device, in accordance with some embodiments of the present disclosure.

FIG. 2 illustrates a top view of the semiconductor device shown in FIG. 1, in accordance with some embodiments of the present disclosure.

FIG. 3A illustrates a cross-sectional side view along line A-A of the semiconductor device shown in FIG. 2, in accordance with some embodiments of the present disclosure.

FIG. 3B illustrates a cross-sectional side view along line B-B of the semiconductor device shown in FIG. 2, in accordance with some embodiments of the present disclosure.

FIG. 3C illustrates a cross-sectional side view along line C-C of the semiconductor device shown in FIG. 2, in accordance with some embodiments of the present disclosure.

FIG. 4 is a perspective view of the circled portion A of the semiconductor device shown in FIG. 1, in accordance with some embodiments of the present disclosure.

FIGS. 5A to 5E are top views of the semiconductor device in accordance with various embodiments of the present disclosure.

FIGS. 6A to 6D are top views of a portion the semiconductor device in accordance with some embodiments of the present disclosure.

FIGS. 7A to 7D are top views of the semiconductor device in accordance with various embodiments of the present disclosure.

FIG. 8A is a top view of the semiconductor device in accordance with an embodiment of the present disclosure.

FIG. 8B is a cross-sectional side view along line D-D of the semiconductor device shown in FIG. 8A, in accordance with an embodiment of the present disclosure.

FIG. 9A is a top view of the semiconductor device in accordance with an alternative embodiment of the present disclosure.

FIG. 9B is a cross-sectional side view along line D-D of the semiconductor device shown in FIG. 9A, in accordance with an embodiment of the present disclosure.

FIG. 10A is a top view of the semiconductor device in accordance with an alternative embodiment of the present disclosure.

FIG. 10B is a cross-sectional side view along line D-D of the semiconductor device shown in FIG. 10A, in accordance with an embodiment of the present disclosure.

FIG. 11A is a top view of the semiconductor device in accordance with an alternative embodiment of the present disclosure.

FIG. 11B is a cross-sectional side view of the semiconductor device shown in FIG. 8A in accordance with an embodiment of the present disclosure.

FIG. 12 is a flowchart of a method for forming the semiconductor device in accordance with some embodiments.

FIGS. 13A to 13E illustrate various perspective views of forming the semiconductor device in accordance with some embodiments as described in FIG. 12.

FIGS. 14A to 14C illustrate cross-sectional side views along line A′-A′ of the semiconductor device shown in FIGS. 13A to 13C, respectively, in accordance with some embodiments of the present disclosure.

FIG. 14D illustrates a cross-sectional side views along line A′-A′ of the semiconductor device shown in FIG. 13E in accordance with some embodiments of the present disclosure.

FIGS. 15A and 15B illustrate various cross-sectional side views along line B′-B′ of the semiconductor device shown in FIGS. 13D to 13E, respectively, in accordance with some embodiments of the present disclosure.

FIG. 16 illustrates a top view of the semiconductor device shown in FIG. 13C without showing a sacrificial layer in accordance with some embodiments of the present disclosure.

FIG. 17 illustrates a top view of the semiconductor device shown in FIG. 13E in accordance with some embodiments of the present disclosure.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

A comparative semiconductor-on-insulator (SOI) structure comprises a substrate, an insulator formed on the substrate and a layer of semiconductive material formed on the insulator, so that the insulator isolates the layer of semiconductive material from the substrate. However, such insulator can only provide a single-direction isolation and require high costs. Alternatively, anti-doped implantation may be conducted to provide a full direction junction isolation. However, such junction isolation may bring parasitic capacitance and would reduce device performance. Furthermore, the isolation ability of the junction isolation may be worse than that of the insulator. There is a need to provide a cost effective isolation structure with superior full direction isolation and less parasitic effect.

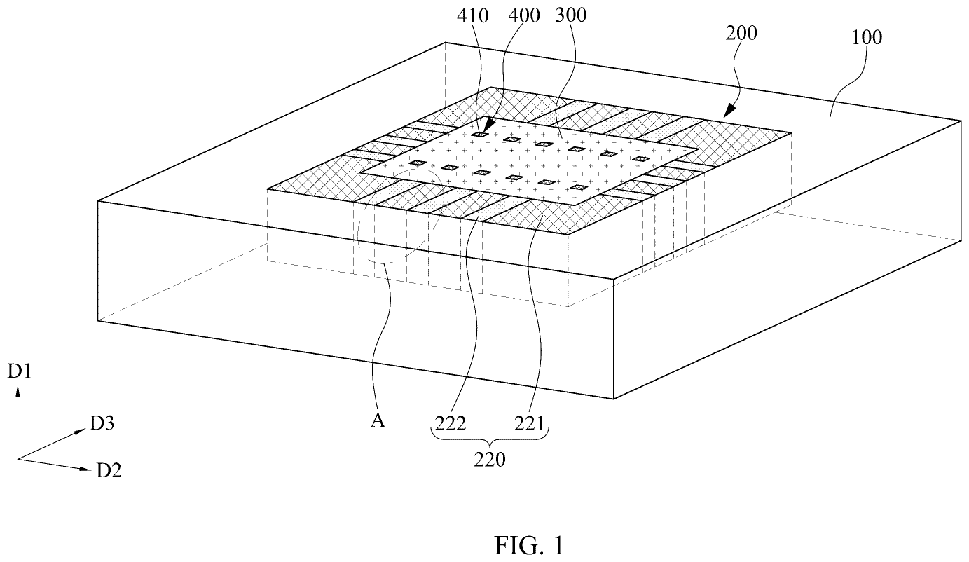

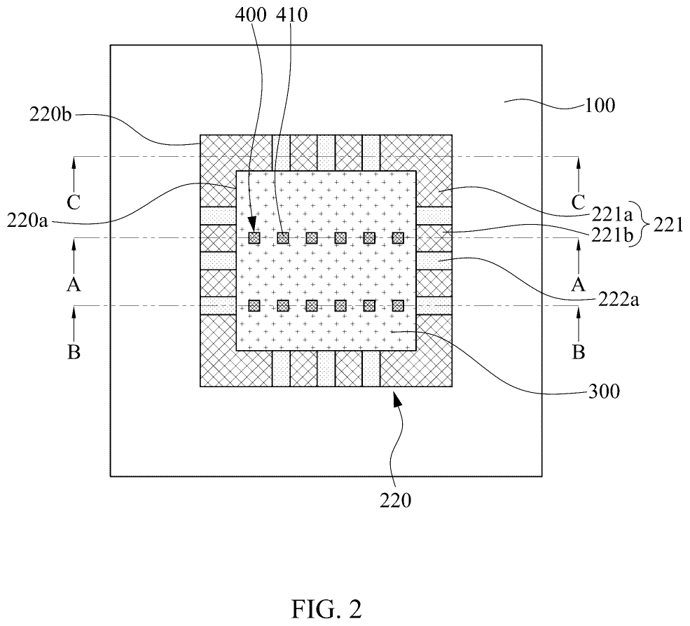

Referring to FIG. 1 and 2, the semiconductor device includes a first semiconductive region 100, an isolation structure 200, a second semiconductive region 300 separating from the first semiconductive region 100 through the isolation structure 200, and a via array 400.

The first semiconductive region 100 may be formed in the semiconductor device using metal-organic chemical vapor deposition (MOCVD), molecular beam epitaxy (MBE), liquid phase epitaxy (LPE), vapor phase epitaxy (VPE), selective epitaxial growth (SEG), the like, or a combination thereof. In some embodiments, the first semiconductive region 100 comprises SiGe, Ge, GeSn, SiGeSn, or a III-V material. In embodiments wherein the first semiconductive region 100 comprises a III-V material, the first semiconductive region 100 may comprise InAs, AlAs, GaAs, InP, GaN, InGaAs, InAlAs, GaSb, AlSb, AlP, or GaP, as examples. The first semiconductive region 100 may comprise a thickness of about 3 nm to about 30 nm, or about 10 nm to about 20 nm, for example. The first semiconductive region 100 may also comprise other materials and dimensions, and may be formed using other methods.

The isolation structure 200 is formed in the first semiconductive region 100. In some embodiments, the isolation structure 200 has an isolation bottom 210 and an isolation ring 220. A top of the isolation structure 200 may be substantially coplanar with a top of the first semiconductive region 100. The isolation bottom 210 is formed in the first semiconductive region 100 and may comprise oxide, nitride, carbide, low k materials or a combination thereof. For example, the isolation bottom 210 may comprise silicon oxide, doped silicon oxide, silicon carbide, silicon nitride and so on. These are, of course, merely examples and are not intended to be limiting.

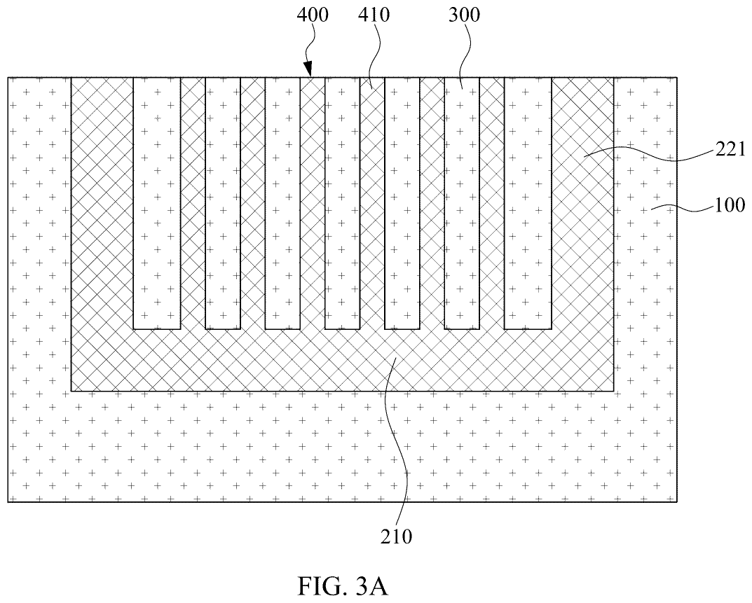

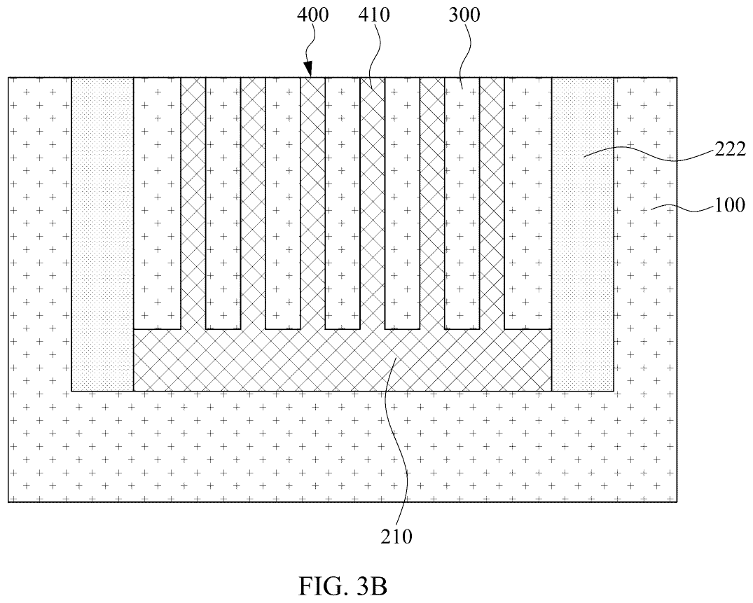

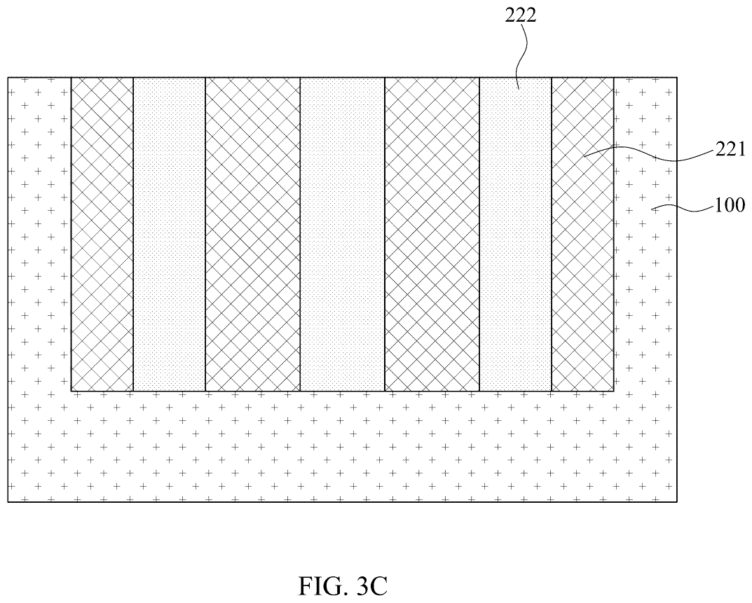

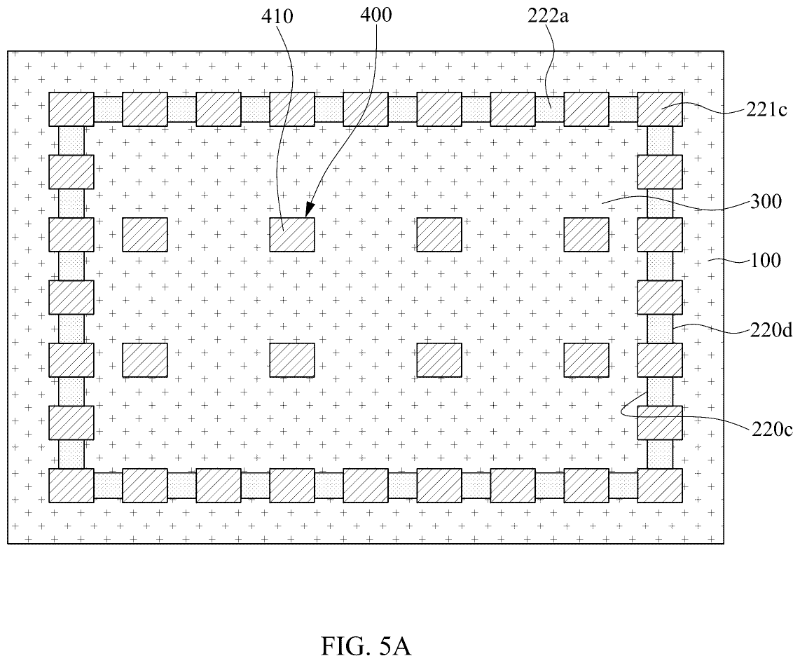

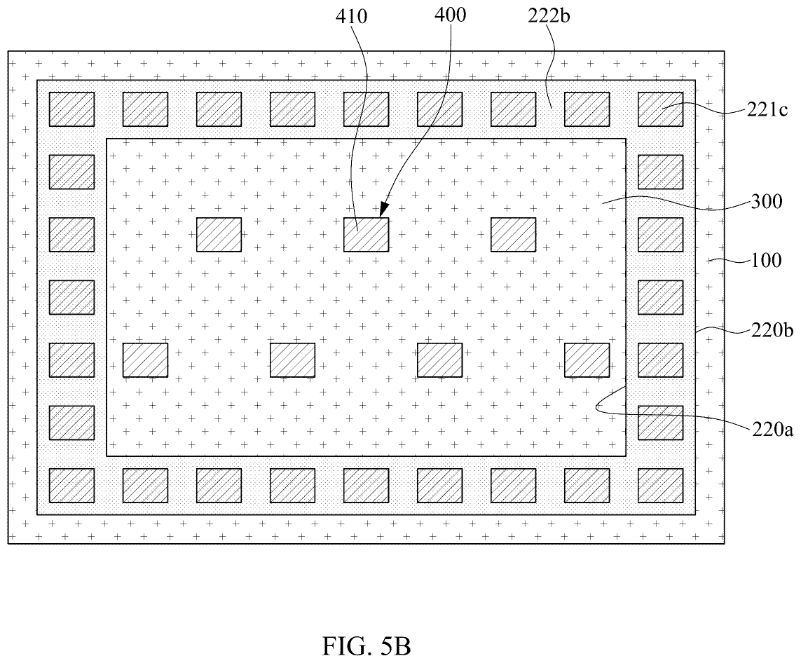

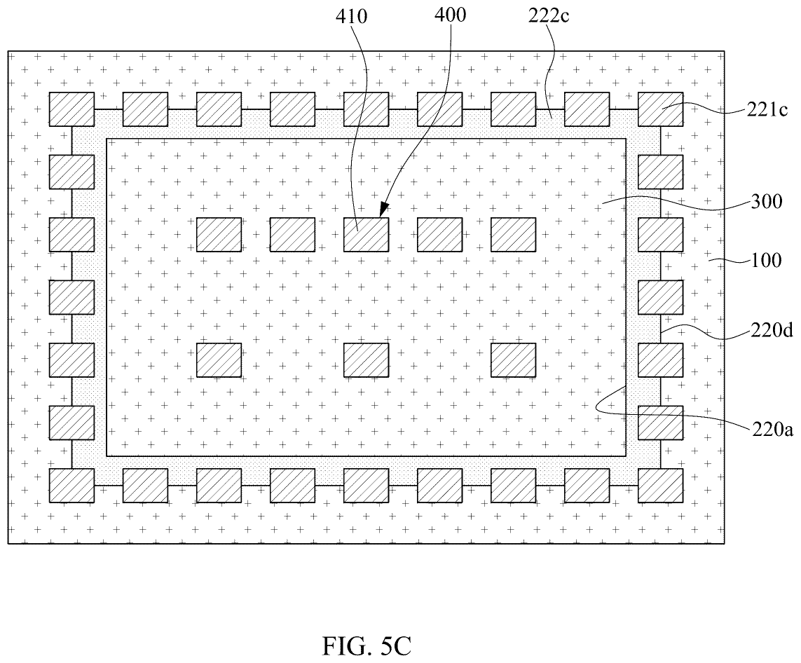

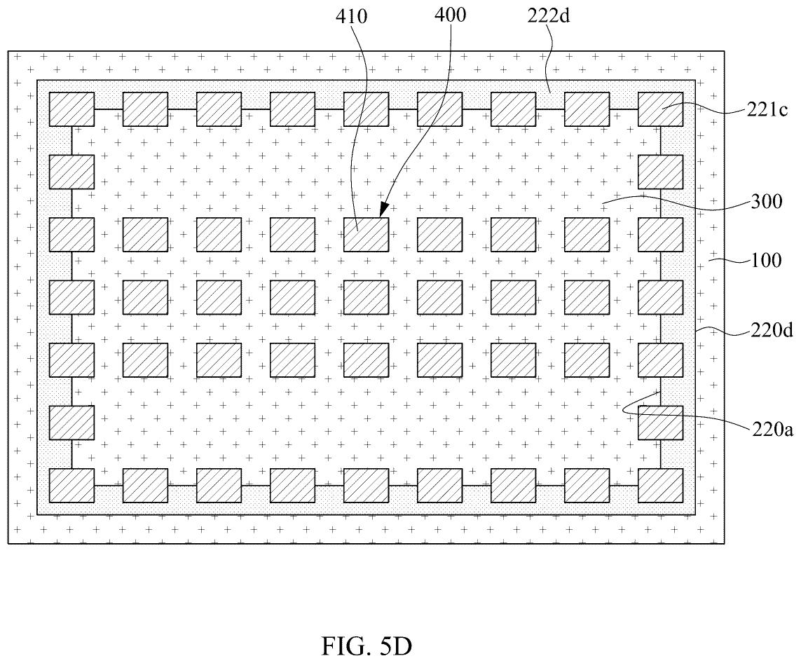

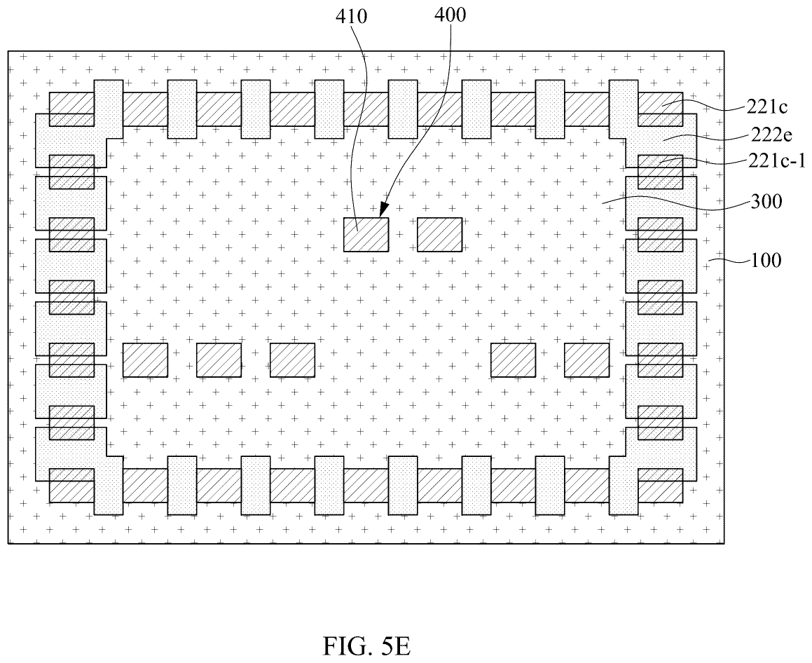

With further reference to FIGS. 3A to 3C, the isolation ring 220 has a lower portion connecting the isolation bottom 210 and an upper portion surrounding the second semiconductive region 300. The isolation ring 220 may be in any shape, such as a rectangular shape (as shown in FIG. 1), a triangular shape, circular shape, or other regular or irregular shapes. These are, of course, merely examples and are not intended to be limiting. The isolation ring 220 comprises a plurality of insulating regions 221 and a plurality of doped regions 222. The plurality of doped regions 222 may be formed separately by the insulating regions 221 as shown in FIGS. 2 and 5A or may be formed continuously by partially or completely overlapping the insulating regions 221 as shown in FIGS. 5B to 5E. The plurality of doped regions 222 connect the isolation bottom 210. In some embodiments, the plurality of doped regions 222 may be formed on the isolation bottom 210. In some alternative embodiments, the plurality of doped regions 222 may be formed in the first semiconductive region 100 and adjacent to the isolation bottom 210. In some alternative embodiments, the plurality of doped regions 222 may be partially formed in the semiconductive region 100 and partially formed on the isolation bottom 210.

A ratio of the plurality of insulating regions 221 to the isolation ring 220 may range from about 10 vol. % to about 90 vol. % according to required process/product window. In some embodiments, the ratio of the plurality of insulating regions 221 to the isolation ring 220 may range from about 20 vol. % to about 80 vol. %. In some embodiments, the ratio of the plurality of insulating regions 221 to the isolation ring 220 may range from about 30 vol. % to about 70 vol. %. As shown in FIGS. 1 and 2, the plurality of insulating regions 221 and the plurality of doped regions 222 may be formed alternately along a second direction D2 and a third direction D3. Alternatively, the plurality of insulating regions 221 and the plurality of doped regions 222 may partially overlap.

FIG. 3A is a cross-sectional side view along line A-A of the semiconductor device shown in FIG. 2. As shown in FIG. 3A, the plurality of insulating regions 221 connect the isolation bottom 210. The plurality of insulating regions 221 may comprise a material substantially identical to or different from the material for forming the isolation bottom 210. The plurality of insulating regions 221 may comprise insulating materials, including but not limited to oxide, nitride, carbide, low k materials or a combination thereof. For example, the plurality of insulating regions 221 may comprise silicon oxide, doped silicon oxide, silicon carbide, silicon nitride and so on. These are, of course, merely examples and are not intended to be limiting. The plurality of insulating regions 221 may have various shapes, including rectangular, circular, and so on.

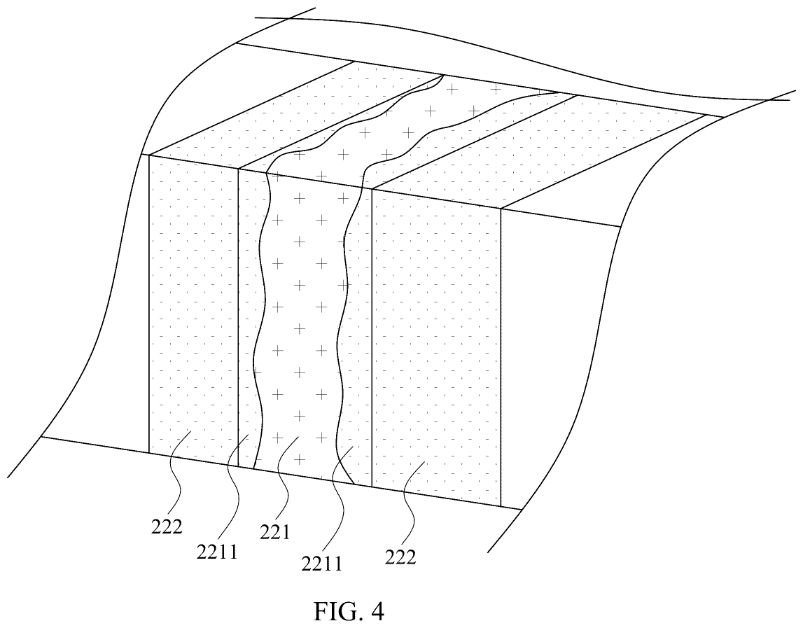

As shown in FIG. 4, which is a perspective view of the circled portion A of the semiconductor device shown in FIG. 1, each insulating region 221 may comprise doped insulating regions 2211 along side surfaces of the insulating region 221 abutting the doped regions 222 since dopants for forming the doped regions 222 would diffuse into the insulating regions 221 during or after the formation of the doped regions 222.

FIG. 3B is a cross-sectional side view along line B-B of the semiconductor device shown in FIG. 2 and FIG. 3C is a cross-sectional side view along line C-C of the semiconductor device shown in FIG. 1. As shown in FIGS. 3B and 3C, the plurality of doped regions 222 connect the isolation bottom 210 and each of the doped regions 222 is formed between two of the plurality of insulating regions 221. The doped regions 222 may have insulating dopants, such as dopants of a conductivity type complementary to those of the first semiconductive region 100 and the second semiconductive region 300, and thus provide insulating effects. For example, when the first semiconductive region 100 and the second semiconductive region 300 are p-type metal oxide semiconductor (PMOS), the doped regions 222 comprises n-type dopants; and when the first semiconductive region 100 and the second semiconductive region 300 are n-type metal oxide semiconductor (NMOS), the doped regions 222 comprise p-type dopants. For example, the p-type dopants may be boron (for example, BF₂), indium, gallium, other p-type dopant, or combinations thereof and the n-type dopants may be phosphorus, arsenic, other n-type dopant, or combinations thereof.

The second semiconductive region 300 is located on the isolation bottom 210 of the isolation structure 200 and is surrounded by the isolation ring 220. The second semiconductive region 300 may have a material substantially identical to the material of the first semiconductive region 100. A top of the second semiconductive region 300 is substantially coplanar with the top of the first semiconductive region 100 and the top of the isolation structure 200. An area of the top of the second semiconductive region 300 may range from about 0.1 nm² to 107 mm².

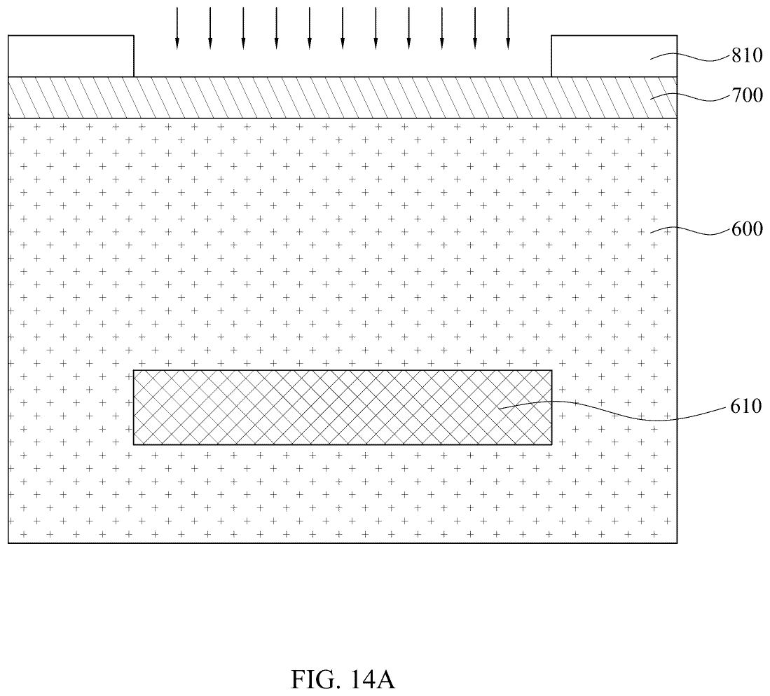

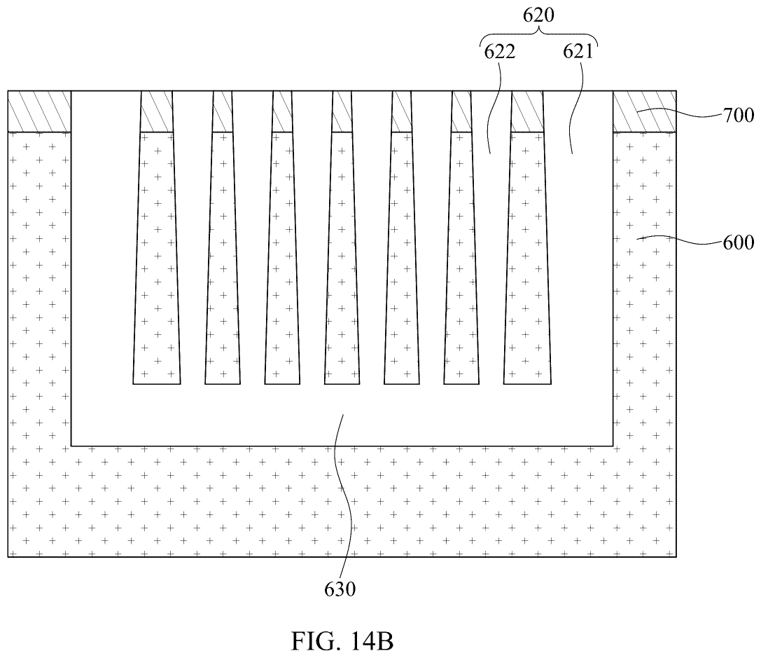

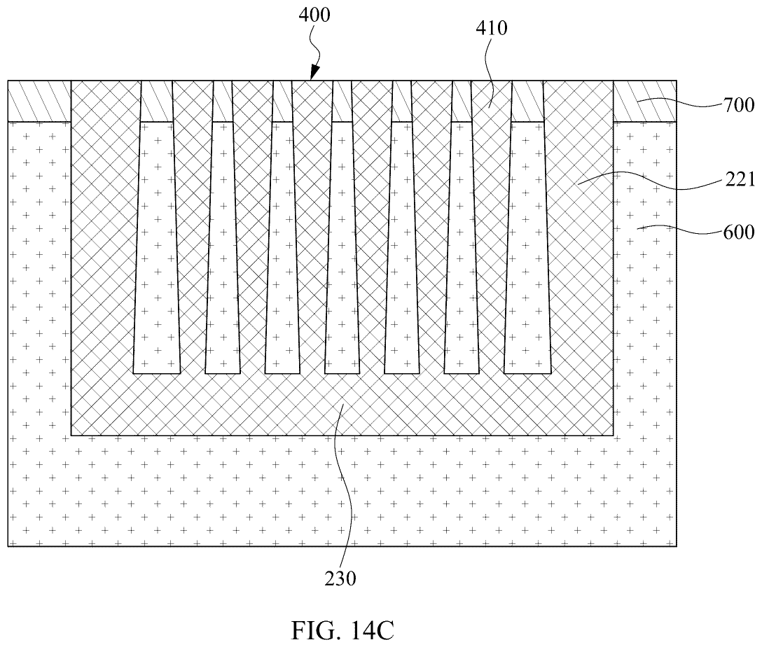

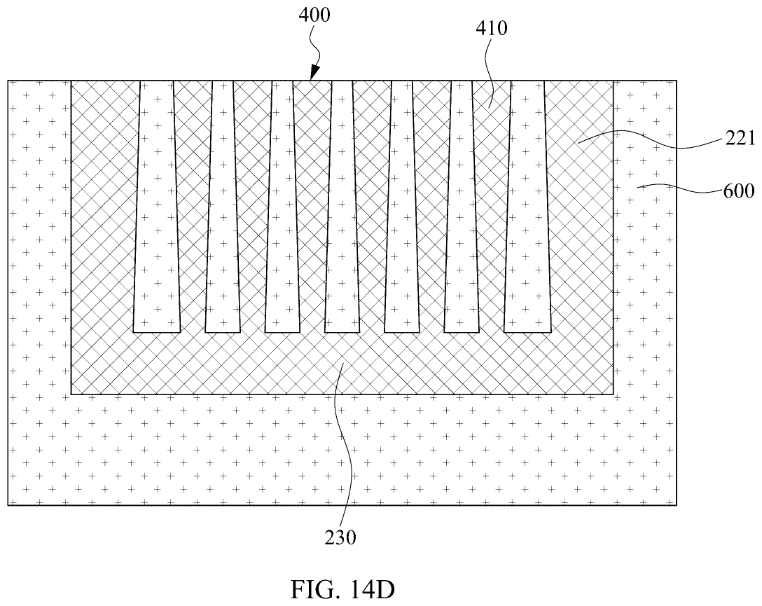

The via array 400 comprises at least one inner insulating via 410 formed in the second semiconductive region 300 and on the isolation bottom 210. The inner insulating vias 410 may comprise oxide (such as SiO, doped SiO and so on), nitride (such as SiN), carbide (such as SiC), low k materials or a combination thereof. For example, the inner insulating vias 410 may comprise silicon oxide, doped silicon oxide, silicon carbide, silicon nitride and so on. These are, of course, merely examples and are not intended to be limiting. Materials of the inner insulating vias 410 may be substantially identical to or different from materials of the isolation structure 200. As shown in FIG. 14D, in some embodiments, each inner insulating via 410 has a top with an area larger than an area of a bottom of the inner insulating via 410. In some alternative embodiments, the each inner insulating via 410 may have a top with an area substantially identical to an area of a bottom of the inner insulating via 410.

In some embodiments, with reference to FIG. 2, the isolation ring 220 may have a rectangular top view and has four L-shape insulating regions 221a, a plurality of rectangular insulating regions 221b and a plurality of rectangular doped regions 222a formed between the L-shape insulating regions 221a and the rectangular insulating regions 221b and between the rectangular insulating regions 221b. Inner surfaces of the L-shape insulating regions 221a and the rectangular insulating regions 221b can be aligned with inner surfaces of the rectangular doped regions 222a so that an inner surface 220a of the isolation ring 220 may form a substantially flat rectangular edge. Therefore, the second semiconductive region 300 is a tetrahedron. Outer surfaces of the L-shape insulating regions 221a and the rectangular insulating regions 221b can be aligned with inner surfaces of the rectangular doped regions 222a so that an outer surface 220b of the isolation ring 220 may form a substantially flat rectangular edge.

In some another embodiments, with reference to FIG. 5A, the isolation ring 220 may comprise a plurality of rectangular insulating regions 221c and a plurality of rectangular doped regions 222a formed between the rectangular insulating regions 221c. An area of a top surface of each of the plurality of rectangular doped regions 222a is smaller than an area of a top surface of each of the rectangular insulating regions. Therefore, inner surface 220c of the isolation ring 220 may be a serrated surface and an outer surface 220d of the isolation ring 220 may be a serrated surface.

In some alternative embodiments, with reference to FIG. 5B, the isolation ring 220 may have a rectangular top view and has a doped ring 222b and a plurality of insulating regions 221c formed in the doped ring 222b at regular or irregular intervals. The insulating regions 221c may be completely covered by the doped ring 222b. An inner surface of the doped ring 222b serves as an inner surface 220a of the isolation ring 220, which is a substantially flat surface; and an outer surface of the doped ring 222b serves as an outer surface 220b of the isolation ring 220, which is a substantially flat surface. There is an interval between an inner surface of each of the insulating regions 221c and the inner surface of the doped ring 222b. There is an interval between an outer surface of each of the insulating regions 221c and the inner surface of the doped ring 222b.

In some alternative embodiments, with reference to FIG. 5C, the isolation ring 220 has a doped ring 222c and a plurality of insulating regions 221c formed in the doped ring 222c at regular or irregular intervals. The insulating regions 221c may be partially covered by the doped ring 222c. In this embodiment as shown in FIG. 5C, inner surfaces of the insulating regions 221c are covered by the doped ring 222c and there is an interval between an inner surface of each of the insulating regions 221c and the inner surface of the doped ring 222c. An inner surface of the doped ring 222c serves as an inner surface 220a of the isolation ring 220, which is a substantially flat surface; and an outer surface 220d of the isolation ring 220 may be a serrated surface.

In some alternative embodiments, with reference to FIG. 5D, the isolation ring 220 has a doped ring 222d and a plurality of insulating regions 221c formed in the doped ring 222d at regular or irregular intervals. The insulating regions 221c may be partially covered by the doped ring 222d. In this embodiment as shown in FIG. 5D, outer surfaces of the insulating regions 221c are covered by the doped ring 222d and there is an interval between an outer surface of each of the insulating regions 221c and the outer surface of the doped ring 222d. An outer surface of the doped ring 222d serves as an outer surface 220b of the isolation ring 220, which is a substantially flat surface; and an inner surface 220c of the isolation ring 220 may be a serrated surface.

In some alternative embodiments, with reference to FIG. 5E, the isolation ring 220 has a plurality of insulating regions 221c and a plurality of doped regions 222e, which may partially overlap to form a plurality of overlapping regions 222c-1. The doped regions 222h may partially overlap the isolation ring 220. The isolation ring 220 is a rectangular ring including two long sides and two short sides. In some embodiments, the doped regions 222e on the long side of the isolation ring 220 have different shapes from the doped regions 222e on the short side of the isolation ring 220. As shown in FIG. 5E, each doped regions 222e on the short side of the isolation ring 220 has a top cross section, which is larger than that of each doped regions 222e on the long side of the isolation ring 220.

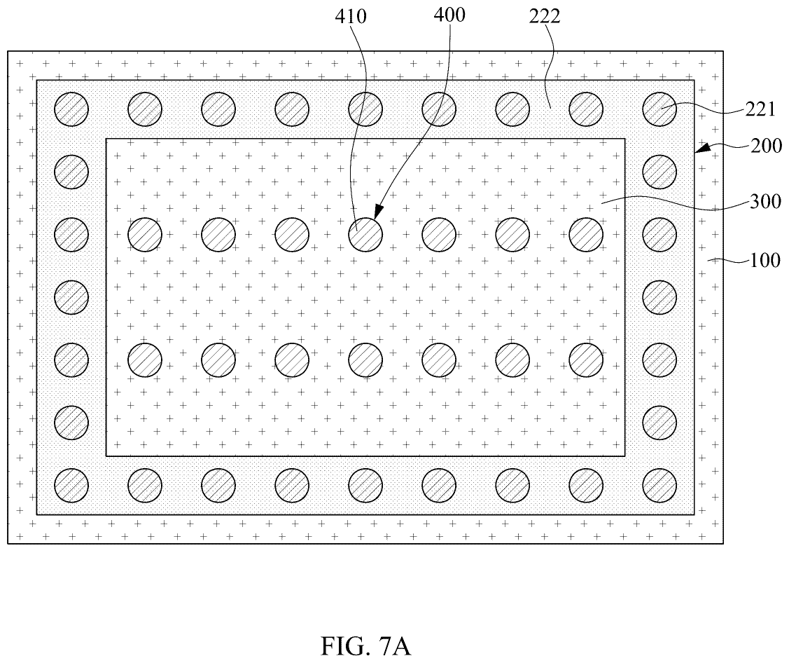

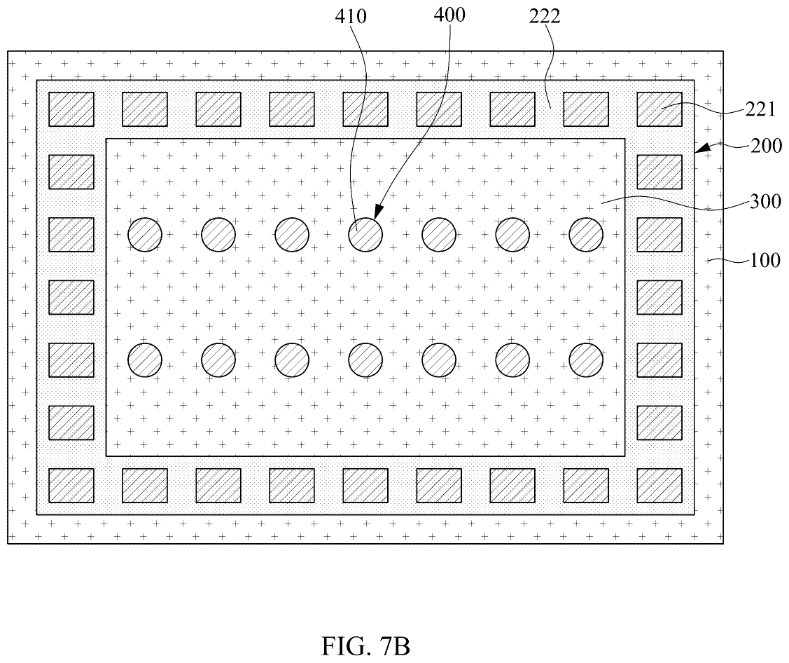

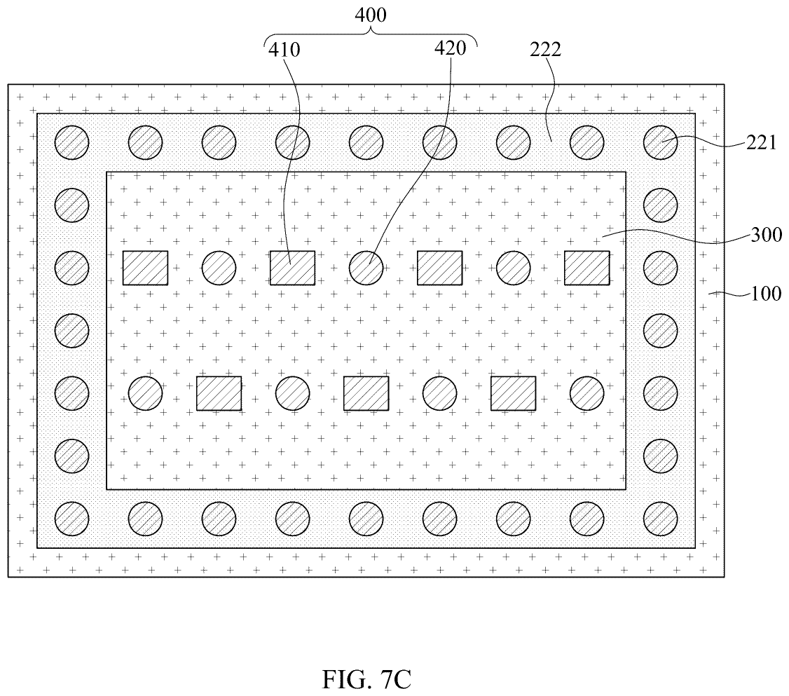

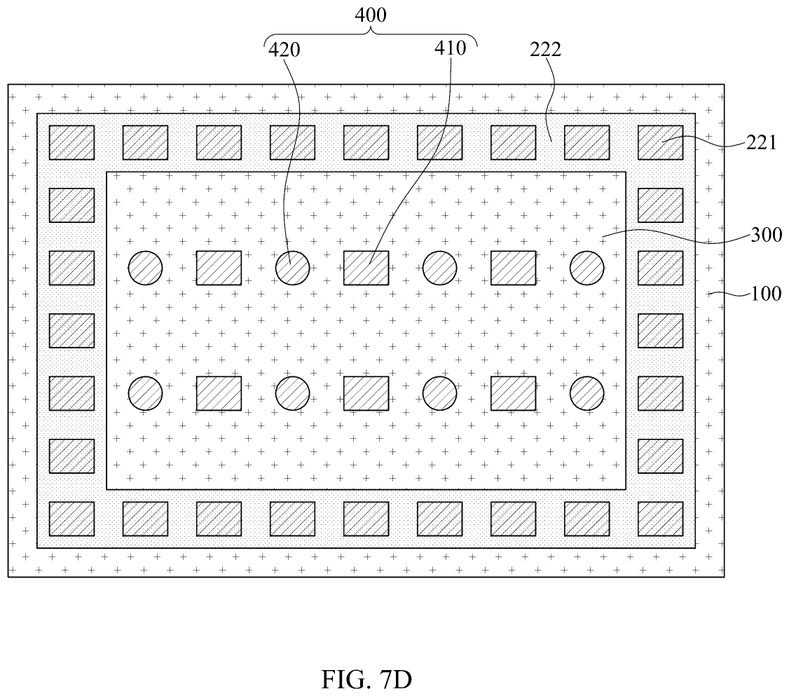

The insulating regions 221 and the doped regions 222 may have different shapes, dimensions and so on. For example, insulating regions 221 has a top cross section, which can be rectangular as shown in FIGS. 5A to 5E, circular as shown in FIGS. 7A and 7C, triangular, or other regular or irregular shapes or a combination thereof. In some embodiments the plurality of insulating regions 221 may be tetrahedron formed at regular or irregular intervals.

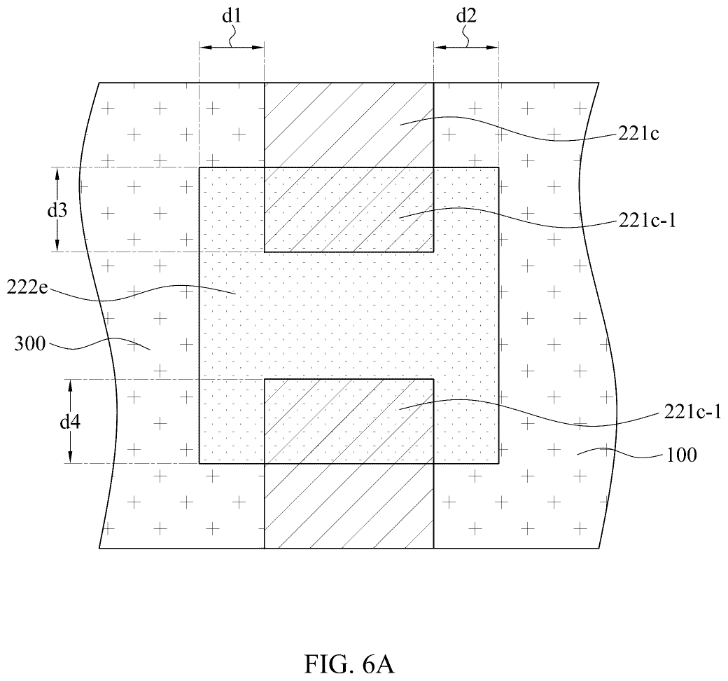

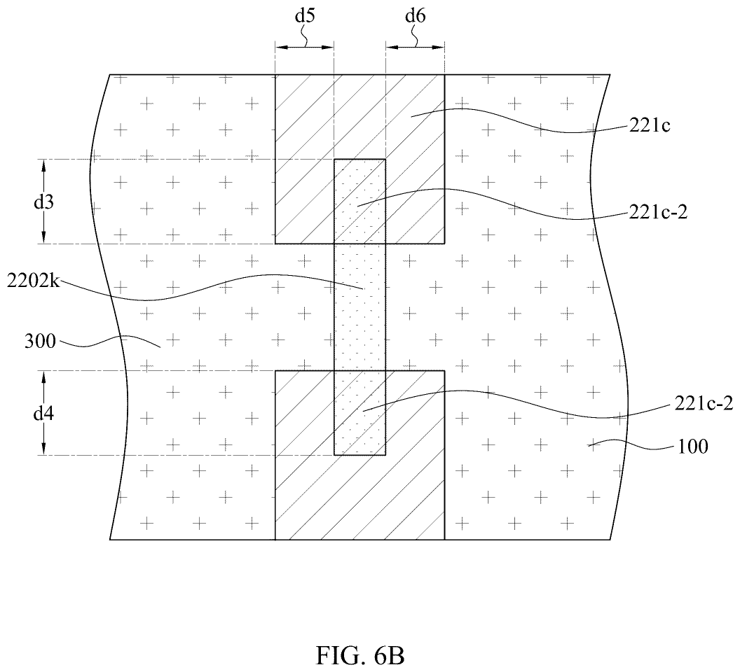

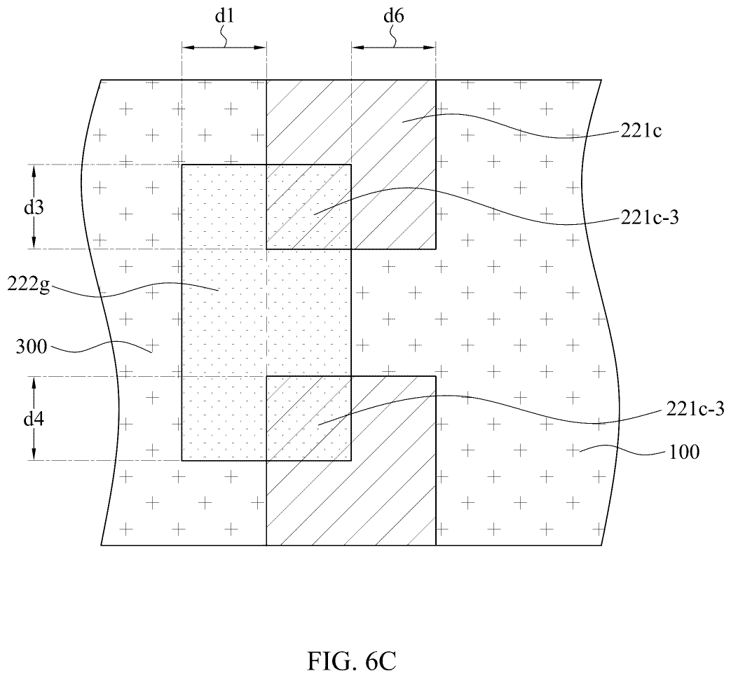

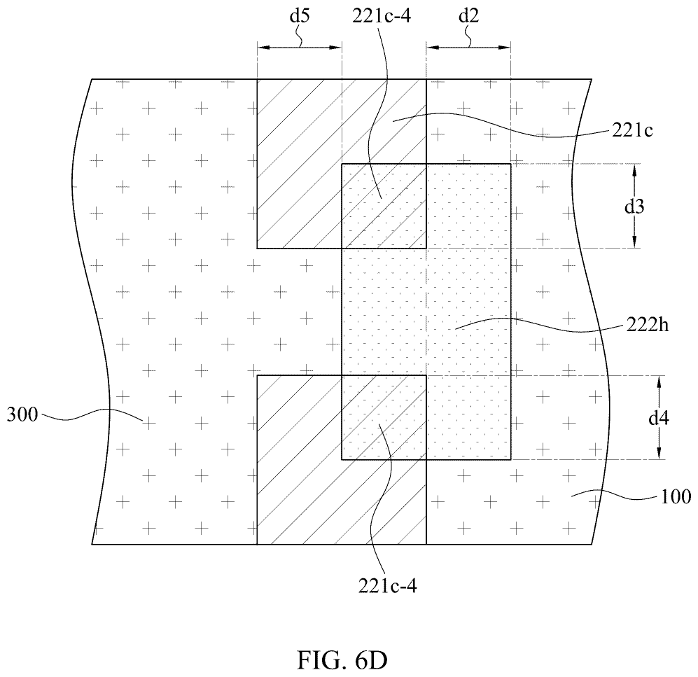

With reference to FIG. 6A, the doped region 222e has an inner surface expanding from an inner surface of the insulating regions 221c toward the second semiconductive region 300 and has an outer surface expanding from an outer surface of the insulating regions 221c toward the first semiconductive region 100. In some embodiments, a distance d₁ between the inner surface of the doped region 222e and the inner surface of the insulating regions 221c may be from about 10 nm to about 1 μm. In some embodiments, a distance d₂ between the outer surface of the doped region 222e and the outer surface of the insulating regions 221c may be from about 10 nm to about 1 μm. The distance d₁ may be substantially identical to the distance d₂ as shown in FIG. 6A or may be different from the distance d₂. Each doped region 222e may expand toward two adjacent insulating region 221c to a distance d₃ and a distance d₄, respectively, to form two overlapping regions 221c-1 in the adjacent insulating regions 221c. In some embodiments, the distance d₃ may be from about 10 nm to about 1 μm and the distance d₄ may be from about 10 nm to about 1 μm. The distance d₃ may be substantially identical to the distance d₄ as shown in FIG. 6A or may be different from the distance d₄.

With reference to FIG. 6B, the doped region 222f has an inner surface retracted toward the first semiconductive region 100 and an outer surface retracted toward the second semiconductive region 300. In some embodiments, a distance d₅ between the inner surface of the doped region 222f and the inner surface of the insulating regions 221c may be from about 10 nm to about 1 μm. In some embodiments, a distance d₆ between the outer surface of the doped region 222f and the outer surface of the insulating regions 221c may be from about 10 nm to about 1 μm. The distance d₅ may be substantially identical to the distance d₆ as shown in FIG. 6B or may be different from the distance d₆. Each doped region 222e may be expanding toward two adjacent insulating region 221c to a distance d₃ and a distance d₄, respectively, to form two overlapping regions 221c-2 in the adjacent insulating regions 221c. In some embodiments, the distance d₃ may be from about 10 nm to about 1 μm and the distance d₄ may be from about 10 nm to about 1 μm. The distance d₃ may be substantially identical to the distance d₄ as shown in FIG. 6A or may be different from the distance d₄.

As shown in FIG. 6C, the doped region 222g has an inner surface expanding toward the first semiconductive region 100 and an outer surface retracted toward the first semiconductive region 100. In some embodiments, a distance d₁ between the inner surface of the doped region 222g and the inner surface of the insulating regions 221c may be from about 10 nm to about 1 μm. In some embodiments, a distance d₆ between the outer surface of the doped region 222g and the outer surface of the insulating regions 221c may be from about 10 nm to about 1 μm. The distance d₅ may be substantially identical to the distance d₆ as shown in FIG. 6C or may be different from the distance d₆. Each doped region 222f may expand toward two adjacent insulating region 221c to a distance d₃ and a distance d₄, respectively, to form two overlapping regions 221c-3 in the adjacent insulating regions 221c. In some embodiments, the distance d₃ may be from about 10 nm to about 1 μm and the distance d₄ may be from about 10 nm to about 1 μm. The distance d₃ may be substantially identical to the distance d₄ as shown in FIG. 6C or may be different from the distance d₄.

As shown in FIG. 6D, the doped region 222h has an inner surface retracted toward the first semiconductive region 100 and an outer surface expanding toward the first semiconductive region 100. In some embodiments, a distance d₅ between the inner surface of the doped region 222h and the inner surface of the insulating regions 221c may be from about 10 nm to about 1 μm. In some embodiments, a distance d₂ between the outer surface of the doped region 222h and the outer surface of the insulating regions 221c may be from about 10 nm to about 1 μm. The distance d₅ may be substantially identical to the distance d₂ as shown in FIG. 6D or may be different from the distance d₂. Each doped region 222h may expand toward two adjacent insulating region 221c to a distance d₃ and a distance d₄, respectively, to form two overlapping regions 221c-4 in the adjacent insulating regions 221c. In some embodiments, the distance d₃ may be from about 10 nm to about 1 μm and the distance d₄ may be from about 10 nm to about 1 μm. The distance d₃ may be substantially identical to the distance d₄ as shown in FIG. 6D or may be different from the distance d₄.

As shown in FIGS. 5A to 5E, the density of the inner insulating vias 410 in the second semiconductive region 300 may be varied depending on the size of the second semiconductive region 300 (for example, from about 0.1 μm² to about 214 μm²), desired performance and design and so on. In some embodiments, each of the inner insulating vias 410 may have a top cross section, which may have a triangular, rectangular, square, trapezoid, polygonal shape or the like. The inner insulating via 410 has different shapes, dimensions and so on. For example, the inner insulating via 410 has a top cross section, which can be rectangular as shown in FIGS. 5A to 5E, circular as shown in FIGS. 7A and 7B, triangular, or other regular or irregular shapes or a combination thereof as shown in FIGS. 7C and 7D.

With reference to FIGS. 7C and 7D, in some another embodiments, the via array 400 comprises a plurality of first inner insulating vias 410 and a plurality of second inner insulating vias 420. The first inner insulating vias 410 and the second inner insulating vias 420 may comprise substantially identical or different materials. Each of the plurality of first inner insulating vias 410 has a top cross section, which is different in shape from that of each of the plurality of second inner insulating via 420 to provide different insulating effects.

In some embodiments, a total area of the top surfaces of the inner insulating vias 410 may occupy about 10% to about 90% of an area of a top surface of the second semiconductive region 300. In some embodiments, the total area of the top surfaces of the inner insulating vias 410 may occupy about 20% to about 80% of an area of a top surface of the second semiconductive region 300. In some embodiments, the total area of the top surfaces of the inner insulating vias 410 may occupy about 30% to about 70% of an area of a top surface of the second semiconductive region 300. In some embodiments the plurality of inner insulating vias 410 may be formed in the second semiconductive region 300 at regular or irregular intervals.

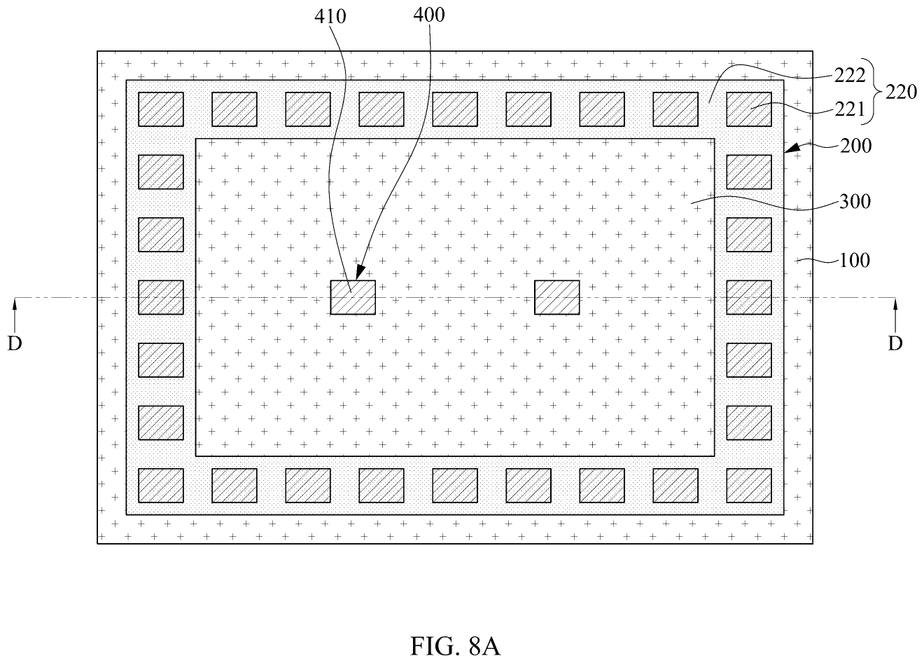

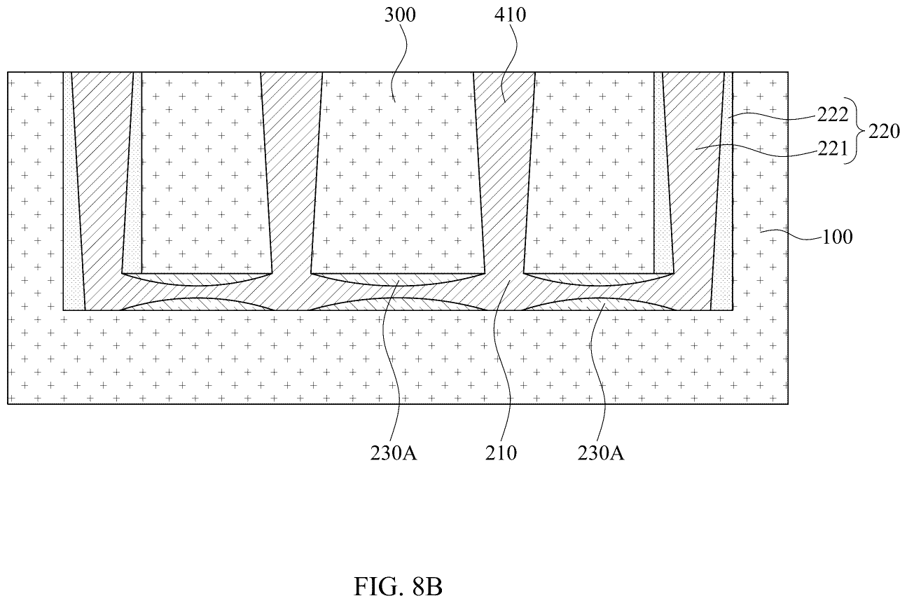

As shown in FIGS. 8A and 8B, in some embodiments, the via array 400 may have two inner insulating vias 410 in the second semiconductive region 300, so the density of the inner insulating vias 410 is low. Therefore, the isolation structure 200 may further comprise at least one embedded doped region 230A, which can be formed on the upper surface of the isolation bottom 210 and/or formed beneath the lower surface of the isolation bottom 210. The embedded doped region 230A comprises materials with a high etching selectivity in respect to the first semiconductive region 100 and a second semiconductive region 300. For example, when the first semiconductive region 100 and the second semiconductive region 300 comprise P-type materials, the embedded doped region 230A may comprise highly doped p-type dopants (e.g., P+ dopants) or even heavily doped p-type dopants (e.g., P++ dopants). The p-type dopants may comprise B, Ga, or In implanted to a concentration equal to or greater than from about 10¹⁵ atoms/cm⁻³. In some embodiments, the concentration may range from about 10¹⁵ atoms/cm⁻³ to 10²⁰ atoms/cm⁻³. When the first semiconductive region 100 and a second semiconductive region 300 comprise n-type materials, the embedded doped region 230A may comprise highly doped n-type dopants (e.g., N+ dopants) or even heavily doped n-type dopants (e.g., N++ dopants). The n-type dopants may be phosphorus, arsenic, other n-type dopant, or combinations thereof.

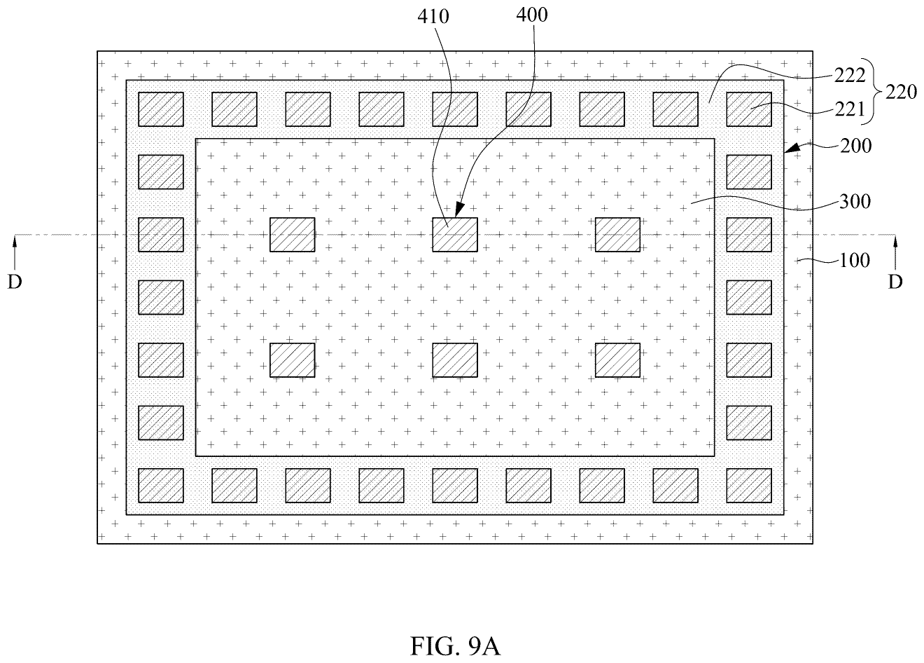

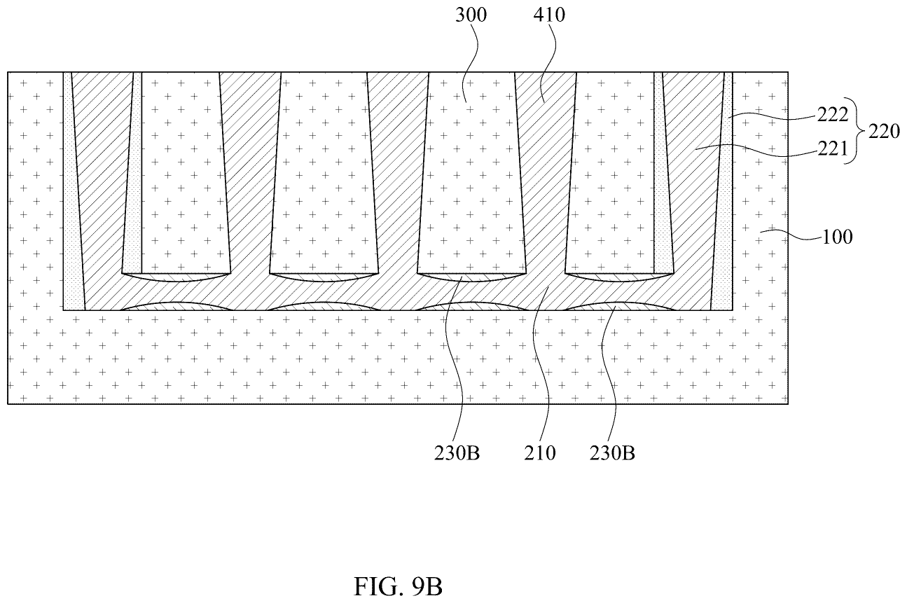

As shown in FIGS. 9A and 9B, in some alternative embodiments, the inner insulating vias 410 of the via array 400 may be increased compared to the embodiment shown in FIGS. 8A and 8B, so the density of the inner insulating vias 410 is increased. The upper surface and the lower surface of the isolation bottom 210 can be more flat and the volume of the embedded doped region 230B shown in FIGS. 9A and 9B would be less than that that shown in FIGS. 8A and 8B.

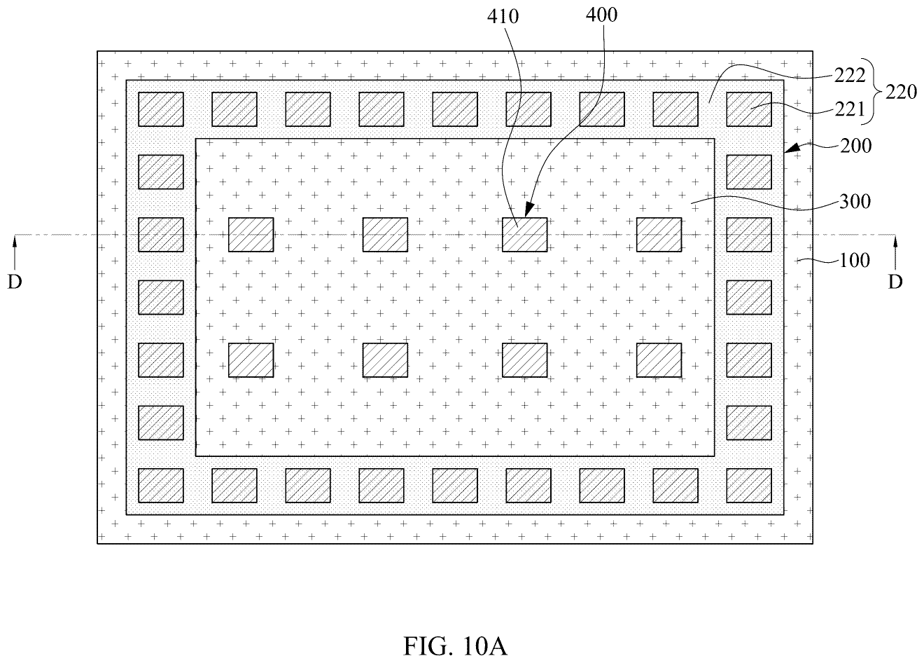

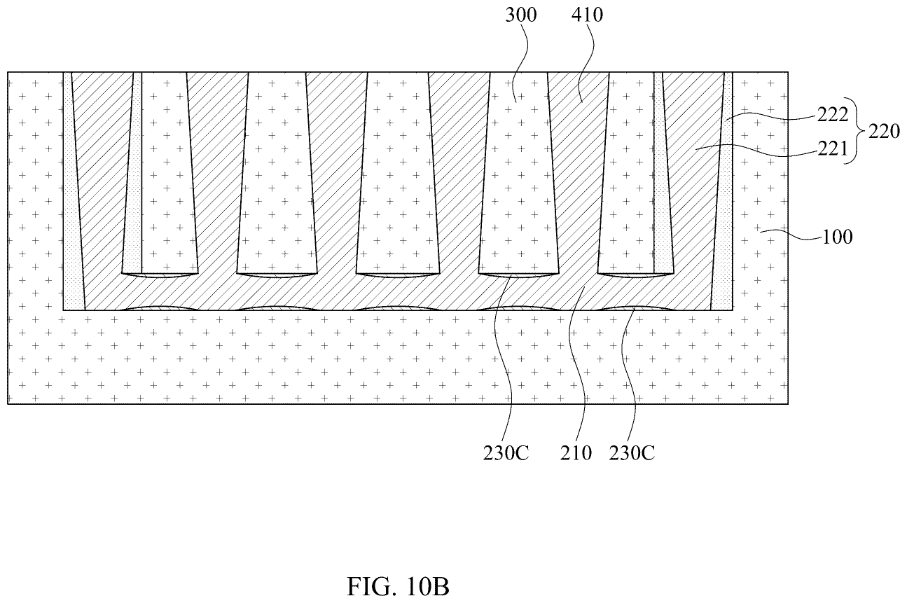

As shown in FIGS. 10A and 10B, in some alternative embodiments, the inner insulating vias 410 of the via array 400 may be increased compared to the embodiment shown in FIGS. 9A and 9B, so the density of the inner insulating vias 410 is increased. The upper surface and the lower surface of the isolation bottom 210 can be more flat and the volume of the embedded doped region 230C shown in FIGS. 10A and 10B would be less than that that shown in FIGS. 9A and 9B.

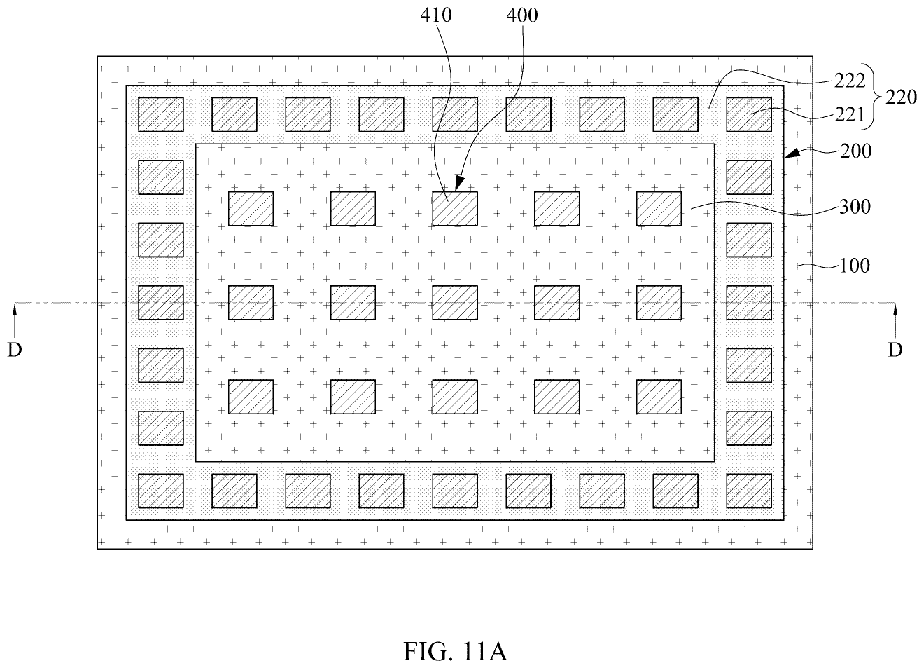

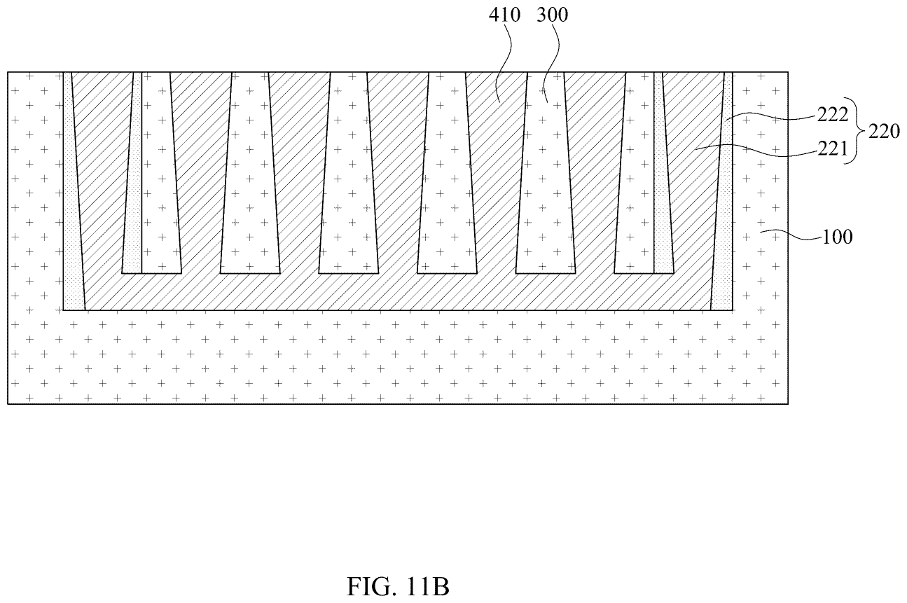

As shown in FIGS. 11A and 11B, in some alternative embodiments, as the density of the inner insulating vias 410 of the via array 400 increases, the upper surface and the lower surface of the isolation bottom 210 can be more flat and may no embedded doped region is formed.

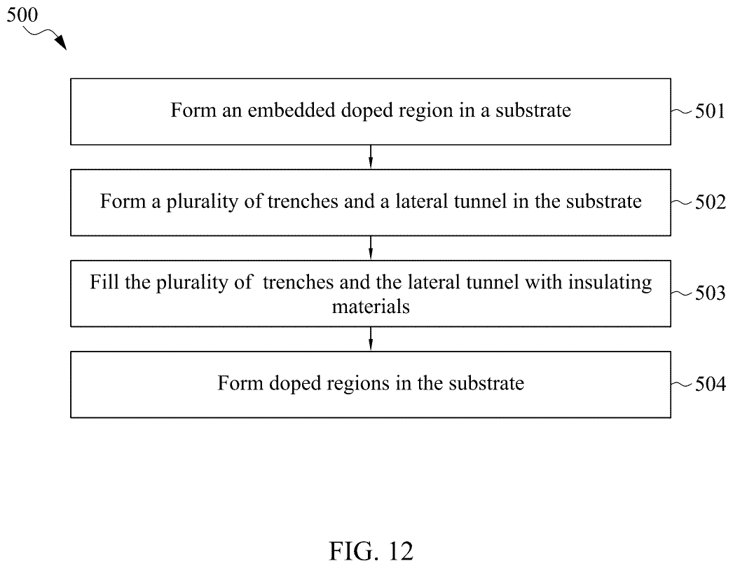

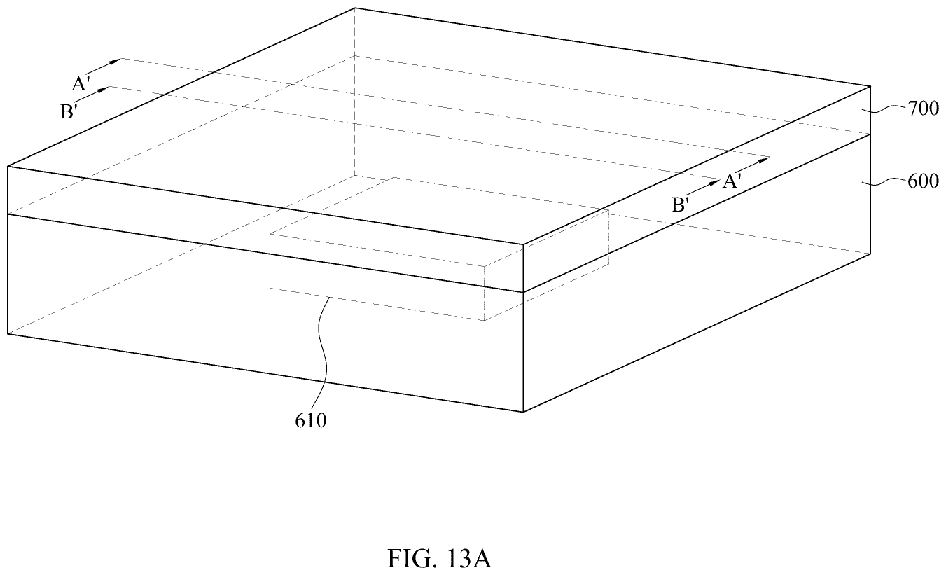

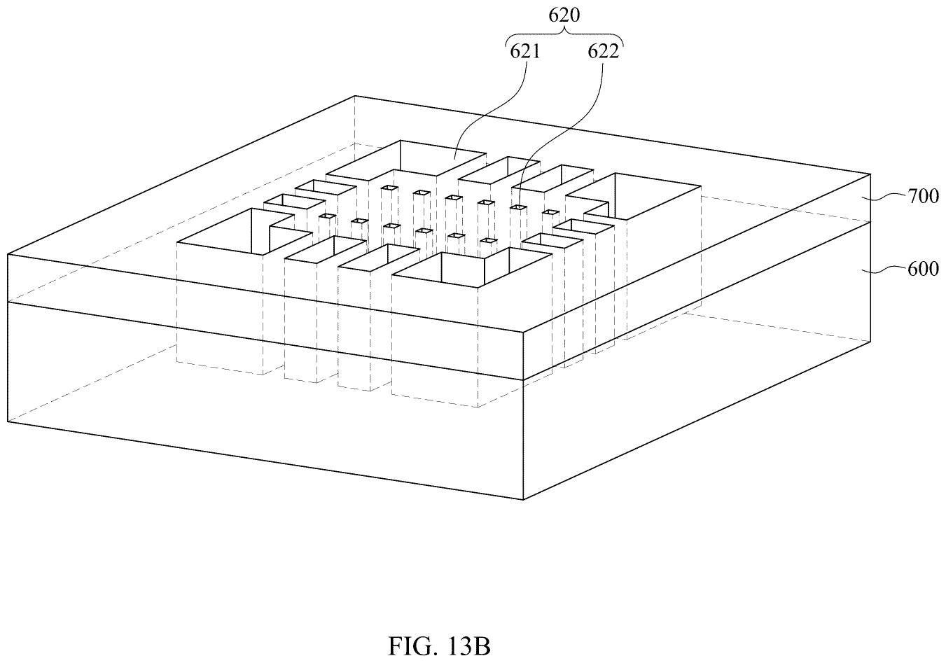

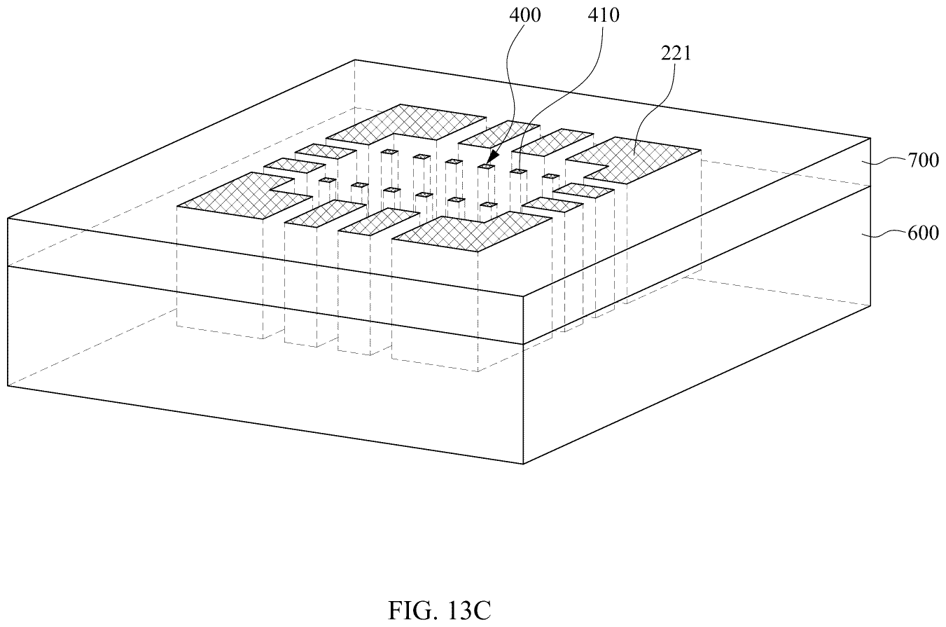

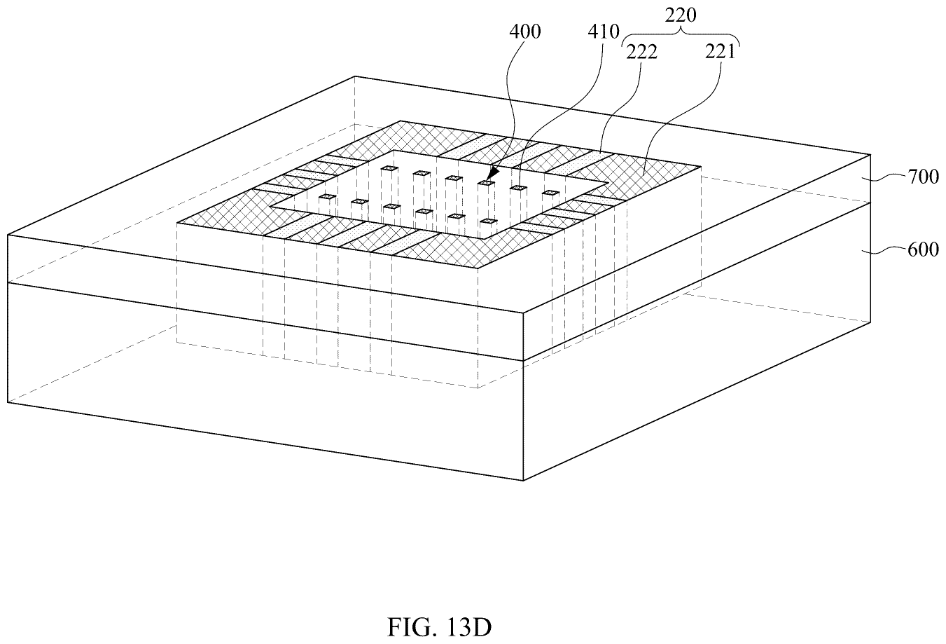

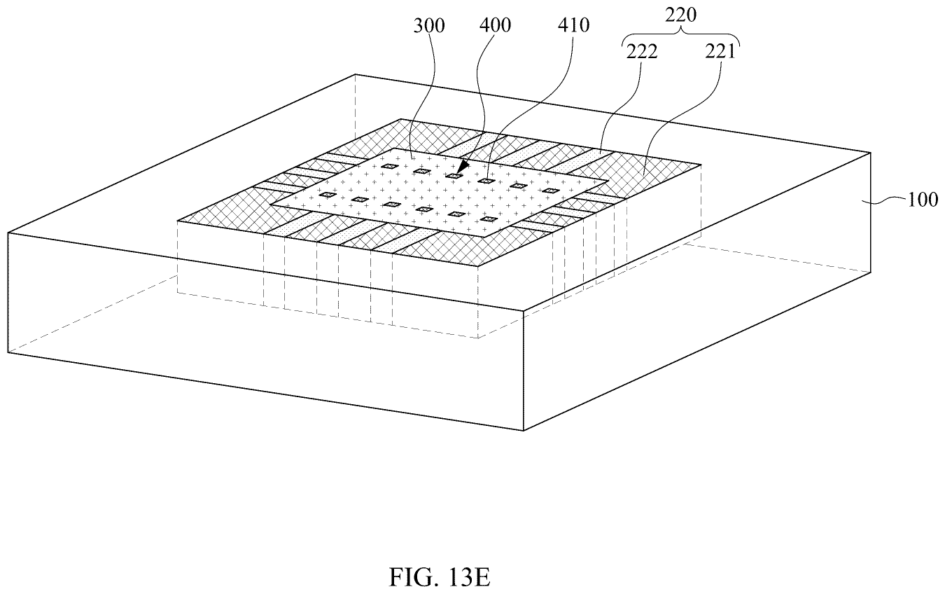

FIG. 12 is a flowchart representing a method 500 for forming a semiconductor device according to various aspects of the present disclosure. In some embodiments, the method 500 for forming the semiconductor device includes a number of operations (501, 502, 503 and 504). The method 500 for forming the semiconductor device will be further described according to one or more embodiments. It should be noted that the operations of the method 500 may be rearranged or otherwise modified within the scope of the various aspects. It should further be noted that additional processes may be provided before, during, and after the method 500, and that some other processes may be only briefly described herein. FIGS. 13A to 13E are diagrammatic perspective views illustrating various stages in the method 500 for forming the connecting structure according to aspects of one or more embodiments of the present disclosure.

With reference to FIGS. 13A and 14A, the method 500 begins at operation 501 where an embedded doped region 610 is formed in a substrate 600 covered with a sacrificial layer 700. At operation 501, the substrate 600 is provided and received, which may be an N-type substrate or a P-type substrate; then, the sacrificial layer 700 is formed over the substrate 600 before forming the embedded doped region 610 through an implantation process. As shown in FIG. 14A, a mask 810 may be used to define the location and shape of the embedded doped region 610. The sacrificial layer 700 may comprise nitride, silicon oxide or the like, which is used to protect the substrate 600 against any damages (such as crystal damage) generated due to the following implantation processes, so as to ensure high device performance. In some embodiments, the thickness of the sacrificial layer 700 may be from about 40 Å to about 80 Å, but the disclosure is not limited thereto. In some comparative approaches, when the thickness of the sacrificial layer 700 is less than 40 Å, it would not be thick enough to protect the substrate 600. In other comparative approaches, when the thickness of the sacrificial layer 700 is greater than 80 Å, it would be too thick to block the following implantation.

According to some embodiments, the embedded doped region 610 is formed in the substrate 600 at a predetermined depth from a top of the substrate 600 through a vertical implantation or a tilt implantation. The embedded doped region 610 formed by doping a predetermined area of the substrate 600 with materials that have a high etching selectivity in respect to the substrate 600. For example, when the substrate 600 is a p-type substrate, the embedded doped region 610 may comprise highly doped p-type dopants (e.g., P+ dopants) or even heavily doped p-type dopants (e.g., P++ dopants). The p-type dopants may comprise B, Ga, or In implanted to a concentration equal to or greater than from about 10¹⁵ atoms/cm⁻³. In some embodiments, the concentration may range from about 10¹⁵ atoms/cm⁻³ to 10²⁰ atoms/cm⁻³. When the substrate 600 is an n-type substrate, the embedded doped region 610 may comprise highly doped n-type dopants (e.g., N+ dopants) or even heavily doped n-type dopants (e.g., N++ dopants). The n-type dopants may be phosphorus, arsenic, other n-type dopant, or combinations thereof. The ion implantation energy, dosage, and temperature of the substrate 600 used during the implantation processes may be designed to control the penetration depth of the dopants in the substrate 600, so that the embedded doped region 610 can be formed at a predetermined depth in the substrate 600.

As shown in FIGS. 13B and 14B, the method 500 continues with operation 502 where a plurality of trenches 620 are formed at intervals by etching the substrate 600 from the top of the substrate 600 downwardly to a depth lower than a top of the embedded doped region 610 to surround the embedded doped region 610; and laterally etching the embedded doped region 610 through the trenches 620 to form a lateral tunnel 630 as shown in FIG. 14B, which communicates the plurality of trenches 620. For example, the plurality of trenches 620 are formed at intervals by etching the substrate 600 from the top of the substrate 600 downwardly to a depth aligned with a bottom of the embedded doped region 610. In some embodiments, a bottom of the plurality of trenches 620 may be in the embedded doped region 610, or abut the embedded doped region 610, or partially overlap the embedded doped region 610. In some embodiments, the plurality of trenches 620 are formed using a dry etch process, a wet etch process, or a suitable process; and the lateral tunnel 630 is formed using a dry etch process, a wet etch process, or a suitable process. For example, the plurality of trenches 620 are formed using a dry etch process and the lateral tunnel 630 is formed using a wet etch process. Since the embedded doped region 610 comprises materials with a high etching selectivity in respect to the substrate 600, the formation of the lateral tunnel 630 can be formed in the embedded doped region 610. An example dry etch may use a fluorine-containing precursor (for example, CF₄, SF₆, NF₃, CH₂F₂, CHF₃, and/or C₂F₆), an oxygen-containing precursor, a chlorine-containing precursor (for example, Cl₂, CHCl₃, CCl₄, and/or BCl₃), a bromine-containing precursor (for example, HBr and/or CHBR₃), an iodine-containing precursor, other suitable precursor (which can be used to generate an etchant gas and/or etching plasma), or combinations thereof. An example of a wet etch process implements an etching solution that includes tetramethylammonium hydroxide (TMAH), NH₄OH, H₂O₂, H₂SO₄, HF, HCl, other suitable wet etching constituent, or combinations thereof.

The plurality of trenches 620 comprise a plurality of peripheral trenches 621 and a plurality of central trenches 622. The plurality of peripheral trenches 621 are formed at intervals by etching the substrate 600 from the top of the substrate 600 downwardly to a depth lower than the top of the embedded doped region 610 to connect the embedded doped region 610. In some embodiments, the plurality of peripheral trenches 621 are formed at intervals by etching the substrate 600 from the top of the substrate 600 downwardly to a depth aligned with a bottom of the embedded doped region 610 to connect the embedded doped region 610. The plurality of central trenches 622 are formed from the top of the substrate 600 downwardly to the embedded doped region 610 and are surrounded by the plurality of peripheral trenches 621.

The lateral etching may be even or uneven depending on the dimension of the embedded doped region 610 and the number of the central trenches 622, so a thickness of the lateral tunnel 630 may be consistent or inconsistent. For example, a thickness of the lateral tunnel 630 may be gradually decreased from an area near the trenches 620 to a central area away from the trenches 620.

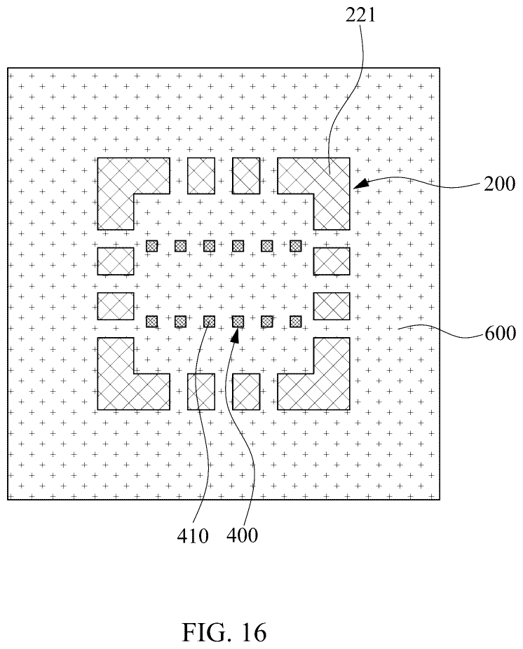

At operation 503, with further reference to FIGS. 13C, 14C and 16, the lateral tunnel 630 is filled with insulating materials to form an isolation bottom 210, the plurality of peripheral trenches 621 are filled with insulating materials to form insulating regions 221 and the plurality of the central trenches 622 are filled with insulating materials to form inner insulating vias 410, so that the isolation bottom 210 connect the insulating regions 221 and the inner insulating vias 410, and the inner insulating vias 410 are formed on the isolation bottom 210 and are surrounded by the insulating regions 221. The insulating materials include but not limited to oxide, nitride, carbide, low k materials or a combination thereof. In some embodiments, the insulating materials may comprise silicon oxide, doped silicon oxide, silicon carbide, silicon nitride and so on. These are, of course, merely examples and are not intended to be limiting.

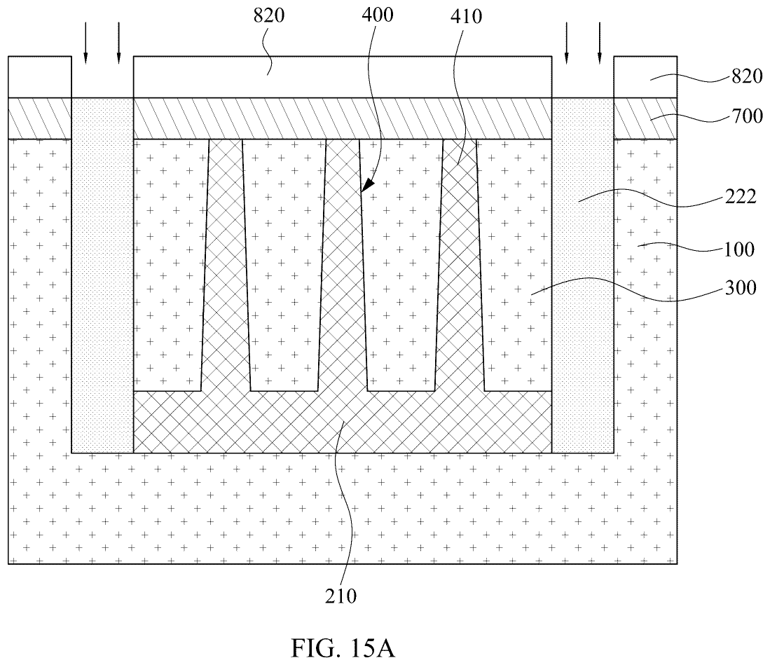

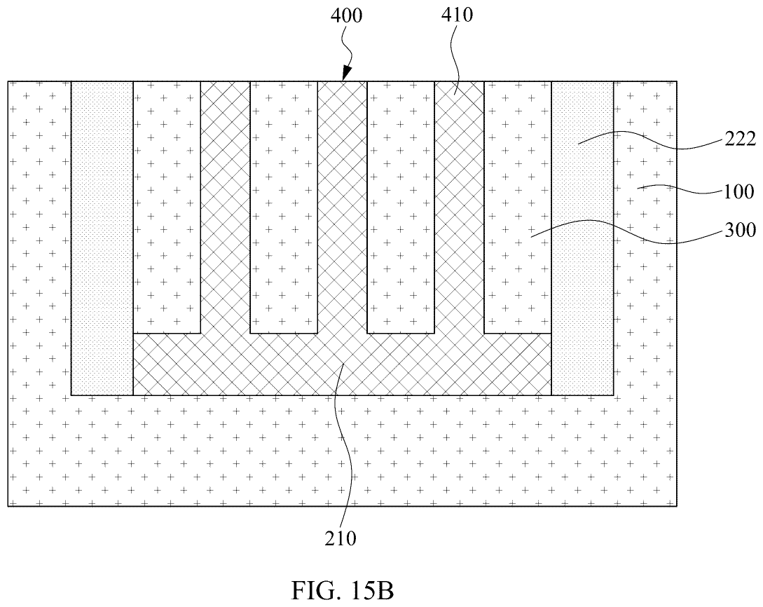

At operation 504, with reference to FIGS. 13D and 15A, a plurality of doped regions 222 can be formed between the insulating regions 221 by implanting intervals between the insulating regions 221 to form an isolation ring 220 by using a mask 820, so that the substrate 600 is divided into a first semiconductive region 100 and a second semiconductive region 300 by the isolation structure 200. Therefore, the first semiconductive region 100 is insulated from the second semiconductive region 300 through the isolation structure 200 including the isolation bottom 210 and the isolation ring 220. The doped regions 222 may have insulating dopants, such as dopants of a conductivity type complementary to those of the first semiconductive region 100 and the second semiconductive region 300, and thus provide insulating effects. The plurality of doped regions 222 may be formed separately by the insulating regions 221 as shown in FIGS. 2 and 5A or may be formed continuously by partially or completely overlapping the insulating regions 221 as shown in FIGS. 5B to 5E.

In addition, a complementary-type implantation may be performed toward the isolation bottom 210 to form at least one doped layer beneath the isolation bottom and/or on the isolation bottom 210 to ensure sufficient isolation effect.

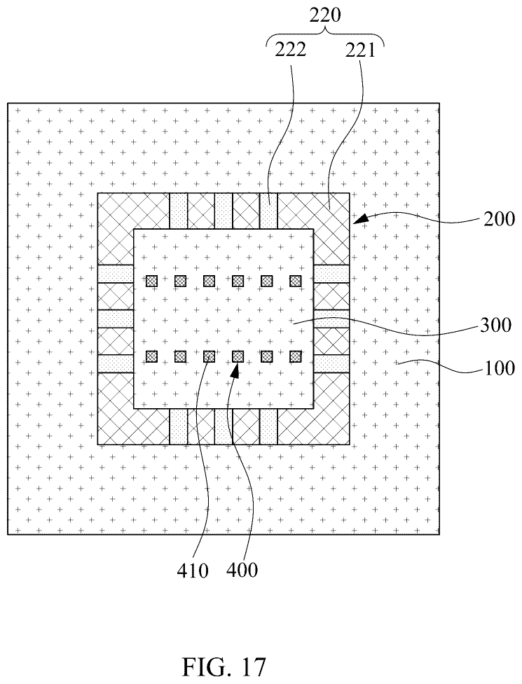

Before conducting following procedures, the sacrificial layer 700 can be removed as shown in FIGS. 13E, 15B and 17 to expose a top of the first semiconductive region 100, a top of the second semiconductive region 300, a top of the isolation ring 220 and tops of the inner insulating vias 410.

The isolation structure 200 provides a better isolation on full direction and less parasitic effect. Further, the alternating insulating regions 221 and doped regions 222 would make the semiconductor device of the present disclosure cost-effective. Furthermore, the formation of the via array 400 provides improved lateral etching uniformity, so the isolation structure 200 of the present disclosure may be applied to various design, in particular a large circuit, which offers design flexibility. The isolation structure 200 provides a better isolation on full direction and less parasitic capacitance within the semiconductor device. With the continuous reduction in device size and the widespread use of multi-voltage applications, the present disclosure provides better isolation in both isolated direction and materials with less parasitic effects, thereby improving device performance.

In some embodiments, a semiconductor device comprises a first semiconductive region; a second semiconductive region; an isolation structure formed between the first semiconductive region and the second semiconductive region and comprising: an isolation bottom formed beneath the second semiconductive region; and an isolation ring with a lower portion connecting the isolation bottom and an upper portion surrounding the second semiconductive region; and at least one inner insulating via formed in the second semiconductive region, on the isolation bottom and surrounded by the isolation ring, wherein the isolation ring comprises a plurality of insulating regions and a plurality of doped regions formed alternately, wherein the isolation bottom and the plurality of insulating regions have insulating materials, and wherein the plurality of doped regions have dopants of a conductivity type complementary to those of the first semiconductive region and the second semiconductive region.

In some embodiments, a semiconductor device comprises a first semiconductive region; a second semiconductive region; and an isolation structure formed between the first semiconductive region and the second semiconductive region and comprising: an isolation bottom formed beneath the second semiconductive region and comprises insulating materials; and an isolation ring with a lower portion connecting the isolation bottom and an upper portion surrounding the second semiconductive region; and a via array comprising a plurality of inner insulating via formed in the second semiconductive region, on the isolation bottom and surrounded by the isolation structure, wherein the isolation ring comprises a doped ring and a plurality of insulating regions formed in the doped ring at intervals, and, and wherein the doped ring has dopants of a conductivity type complementary to that of the first semiconductive region and the second semiconductive region.

In some embodiments, a method for forming a semiconductor device comprises forming an embedded doped region in a substrate; forming a plurality of trenches in the substrate and a lateral tunnel in the embedded doped region, which communicate with each other; filling the plurality of trenches and the lateral tunnel with insulating materials to form a plurality of insulating regions, at least one inner insulating via and an isolation bottom; and forming a plurality of doped regions in the substrate between the plurality of insulating regions, wherein the substrate is divided into a first semiconductive region and a second semiconductive region by the isolation bottom and an isolation ring including the plurality of insulating regions and the plurality of doped regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor device, comprising:
a first semiconductive region;
a second semiconductive region;
an isolation structure formed between the first semiconductive region and the second semiconductive region and comprising:
an isolation bottom formed beneath the second semiconductive region; and
an isolation ring with a lower portion connecting the isolation bottom and an upper portion surrounding the second semiconductive region; and
at least one inner insulating via formed in the second semiconductive region, on the isolation bottom and surrounded by the isolation ring,
wherein the isolation ring comprises a plurality of insulating regions and a plurality of doped regions formed alternately,
wherein the isolation bottom and the plurality of insulating regions have insulating materials, and
wherein the plurality of doped regions have dopants of a conductivity type complementary to those of the first semiconductive region and the second semiconductive region.

2. The semiconductor device of claim 1, wherein each of the plurality of insulating region comprises doped insulating regions along side surfaces abutting adjacent ones of the plurality of doped regions.

3. The semiconductor device of claim 1, wherein each of the plurality of the doped region has an outer surface aligned with an outer surface of an adjacent one of the plurality of insulating regions, and an inner surface aligned with an inner surface of the adjacent one of the plurality of insulating regions.

4. The semiconductor device of claim 1, wherein each of the plurality of the doped region has an outer surface expanding toward the first semiconductive region or retracted toward the second semiconductive region, and an inner surface expanding toward the second semiconductive region or retracted toward the first semiconductive region.

5. The semiconductor device of claim 4, wherein a distance between the inner surface of the doped region and an inner surface of the insulating regions is from about 10 nm to about 1 μm; and a distance between the inner surface of the doped region and an inner surface of the insulating regions is from about 10 nm to about 1 μm.

6. The semiconductor device of claim 1, wherein a ratio of the plurality of insulating regions to the isolation ring is from about 10 vol. % to about 90 vol. %.

7. The semiconductor device of claim 1, wherein the isolation structure further comprises at least one embedded doped region formed on an upper surface of the isolation bottom or beneath a lower surface of the isolation bottom.

8. The semiconductor device of claim 1, wherein a top of the first semiconductive region, a top of the second semiconductive region, a top of the isolation structure and a top of the at least one inner insulating via are substantially coplanar with each other.

9. A semiconductor device, comprising:
a first semiconductive region;
a second semiconductive region;
an isolation structure formed between the first semiconductive region and the second semiconductive region and comprising:
an isolation bottom formed beneath the second semiconductive region and comprises insulating materials; and
an isolation ring with a lower portion connecting the isolation bottom and an upper portion surrounding the second semiconductive region; and
a via array comprising a plurality of inner insulating via formed in the second semiconductive region, on the isolation bottom and surrounded by the isolation structure,
wherein the isolation ring comprises a doped ring and a plurality of insulating regions formed in the doped ring at intervals, and
wherein the doped ring has dopants of a conductivity type complementary to that of the first semiconductive region and the second semiconductive region.

10. The semiconductor device of claim 9, wherein a thickness of the isolation bottom is substantially identical from a central region to a peripheral region.

11. The semiconductor device of claim 9, wherein a thickness of the isolation bottom is substantially identical from an area near the plurality of inner insulating via and the isolation ring to an area away from the plurality of inner insulating via and the isolation ring.

12. The semiconductor device of claim 9, wherein the via array comprises a plurality of first inner insulating vias and a plurality of second inner insulating vias, and wherein an area of the top of each of the plurality of first inner insulating vias is different from that of each of the plurality of second inner insulating via.

13. The semiconductor device of claim 9, wherein the via array comprises a plurality of first inner insulating vias and a plurality of second inner insulating vias, and wherein each of the plurality of first inner insulating vias has a top cross section, which is different in shape from that of each of the plurality of second inner insulating via.

14. The semiconductor device of claim 9, wherein the insulating regions are partially covered by the doped ring.

15. The semiconductor device of claim 9, wherein the insulating regions are completely covered by the doped ring.

16. A method for manufacturing a semiconductor device, comprising:
forming an embedded doped region in a substrate;
forming a plurality of trenches in the substrate and a lateral tunnel in the embedded doped region, which communicate with each other;
filling the plurality of trenches and the lateral tunnel with insulating materials to form a plurality of insulating regions, at least one inner insulating via and an isolation bottom; and
forming a plurality of doped regions in the substrate between the plurality of insulating regions,
wherein the substrate is divided into a first semiconductive region and a second semiconductive region by the isolation bottom and an isolation ring including the plurality of insulating regions and the plurality of doped regions.

17. The method of claim 16, wherein the plurality of trenches comprise
a plurality of peripheral trenches formed at intervals by etching the substrate from a top of the substrate downwardly to a depth lower than a top of the embedded doped region to connect the embedded doped region; and
at least one central trench formed from a top of the substrate downwardly to the embedded doped region and surrounded by the plurality of peripheral trenches,
wherein the plurality of peripheral trenches are filled with the insulating material to form the plurality of insulating regions; and the at least one central trench is filled with the insulating material to form the at least one inner insulating via.

18. The method of claim 16, wherein the isolation structure and the at least one inner insulating via have substantially identical insulating materials.

19. The method of claim 16, wherein the plurality of trenches are formed by dry etching the substrate and the lateral tunnel is formed by wet etching the embedded doped region.

20. The method of claim 16, wherein the embedded doped region has a high etching selectivity in respect to the substrate.
